(19) United States
(12) Patent Application Publication
(10) Pub. No.: US 2007/0084506 A1
(43) Pub. Date: Apr. 19, 2007

(54) Diffraction foils

(76) Inventor: James Ryan, Mamboro, MA (US)

Correspondence Address: FISH & RICHARDSON PC, P.O. BOX 1022, MINNEAPOLIS, MN, 55440-1022, US

(21) Appl. No.: 11/487,107

(22) Filed: Jul. 14, 2006

Related U.S. Application Data
(60) Provisional application No. 60/699,693, filed on Jul. 15, 2005.

(51) Int. Cl. H01L 31/00

(52) U.S. Cl. 136/257

(57) ABSTRACT

Diffraction foils, as well as related photovoltaic cells, systems, components, and methods, are disclosed.

### CROSS REFERENCE TO RELATED APPLICATION

This application claims priority to U.S. Provisional Application Ser. No. 60/699,693, filed Jul. 15, 2005, the contents of which are hereby incorporated by reference.

### TECHNICAL FIELD

This disclosure relates to diffraction foils, as well as related photovoltaic cells, systems, components, and methods.

### BACKGROUND

Photovoltaic cells are commonly used to convert energy in the form of light into energy in the form of electricity. A typical photovoltaic cell includes a photoactive material disposed between two electrodes. Generally, light passes through one or both of the electrodes to interact with the photoactive material to convert light energy into electricity energy.

### SUMMARY

In one aspect, the invention features a photovoltaic cell including a diffraction foil.

In another aspect, the invention features an article that includes a substrate, an photovoltaic cell disposed on the substrate, and a diffraction foil disposed on the photovoltaic cell.

In still another aspect, the invention features a system that includes a photovoltaic cell, a sensor electrically connected with the photovoltaic cell, and a diffraction foil at least partially covering the photovoltaic cell.

Embodiments can include one or more of the following aspects.

The diffraction foil can include a metal, such as aluminum, chromium, copper, silver, gold, or an alloy thereof.

The diffraction foil can include a polymer.

The diffraction foil is configured as at least a portion of an electrode.

The diffraction foil can be configured to direct incoming light to the photoactive layer.

The article can further include two substrates, between which the diffraction foil are disposed.

The article can include an electrically conductive layer coated on the diffraction foil.

The photovoltaic cell further comprises a photoactive material. In some embodiments, the photoactive material can include an electron donor material and an electron acceptor material. In some embodiments, the photoactive material can include a photosensitized interconnected nanoparticle material. In some embodiments, the photoactive material can include amorphous silicon or CIGS.

The electron acceptor material can include a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

The electron donor material can inclue a material selected from the group consisting of discotic liquid crystals, polythiophenes, polyphenylenes, polyphenylvinylenes, polysilanes, polythienylvinylenes, polyisothianaphthalenes, and combinations thereof.

The photosensitized interconnected nanoparticle material can include a material selected from the group consisting of selenides, sulfides, tellurides, titanium oxides, tungsten oxides, zinc oxides, zirconium oxides, and combinations thereof.

The article can include a pattern (e.g., a logo, a number, a letter, a word, a graph, or a design pattern) on a surface.

The diffraction foil can be configured so that, when light impinges on the diffraction foil, the diffraction foil reflects the pattern.

The article can include a security card, an identification card, a greeting card, a business card, an advertising board, a poster, or a sign.

The sensor can be a video sensor, an audio sensor, a movement detecting sensor, a temperature sensor, or a pressure sensor.

The system can be configured to be mounted on a wall.

The system can be configured so that the photovoltaic cell or the sensor is not visible to a naked eye.

During use, the sensor can be at least partially powered by the photovoltaic cell.

Other features and advantages will be apparent from the description, drawings and from the claims.

### DESCRIPTION OF DRAWINGS

FIG. 1 is a cross-sectional view of a diffraction foil disposed on a photovoltaic cell and a substrate;

FIG. 2 is a cross-sectional view of an organic photovoltaic cell;

FIG. 3 is an elevational view of an embodiment of a mesh electrode;

FIG. 4 is a cross-sectional view of the mesh electrode of FIG. 3;

FIG. 5 is a cross-sectional view of a portion of a mesh electrode;

FIG. 6 is a cross-sectional view of another organic photovoltaic cell;

FIG. 7 is a schematic of a system containing multiple photovoltaic cells electrically connected in series;

FIG. 8 is a schematic of a system containing multiple photovoltaic cells electrically connected in parallel; and

FIG. 9 is a cross-sectional view of a dye sensitized solar cell.

Like reference symbols in the various drawings indicate like elements.

### DETAILED DESCRIPTION

In general, this disclosure relates to using a diffraction foil in connection with a photovoltaic cell.

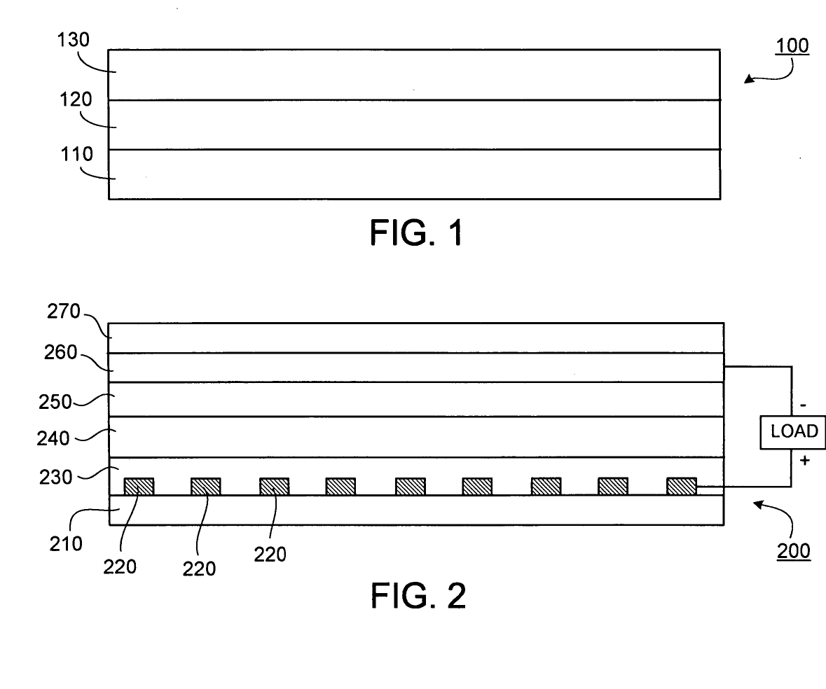

In some embodiments, a diffraction foil can be disposed outside of a photovoltaic cell. FIG. 1 shows an object 100 that contains a diffraction foil 130 secured on top of a photovoltaic cell 120, which in turn is secured to a substrate 110. Diffraction foil 130 can be made of a suitable material, such as a metal or a polymer. Examples of metals that can be used to prepare the diffraction foil include aluminum, chromium, copper, silver, gold, and an alloy thereof. Photovoltaic cell 120 can be an organic photovoltaic cell, a dye sensitized solar cell (DSSC), an amorphous silicon photovoltaic cell, a copper indium gallium selenide (CIGS) photovoltaic cell, a cadmium selenide photovoltaic cell, a cadmium telluride photovoltaic cell, a copper indium sulfide photovoltaic cell, or a tandem photovoltaic cell. Substrate 110 can be prepared from any suitable materials, such as metals or polymers. Object 100 can be, for example, a security card, an identification card, a greeting card, a business card, an advertising board, a poster, or a sign. In some embodiments, object 100 can take on the appearance of a standard object. As an example, object 100 can be mounted on a wall (e.g., to take on the form of an art item, such as a painting or a photo, or a utilitarian object, such as an advertisement). As another example, object 100 can be present on a surface (e.g., a pen, a pencil, a paper holder, a computer components or the like).

In some embodiments, diffraction foil 130 can be secured to photovoltaic cell 120 at some points, and secured to substrate 110 at other points. The points of attachment can vary depend on, for example, the shape of diffraction foil. In some embodiments, diffraction foil 130 is coated on photovoltaic cell 120.

In some embodiments, diffraction foil 130 can be configured to camouflage photovoltaic cell 120. For example, diffraction foil 130 can be configured so that photovoltaic cell 120 is not visible to a naked eye.

In some embodiments, object 100 can include a sensor (not shown in FIG. 1) electrically connected with photovoltaic cell 120 so that light impinging upon photovoltaic cell 120 powers the sensor. During use, the sensor can be at least partially powered by photovoltaic cell 120. Examples of sensors include a video sensor, an audio sensor, a movement detecting sensor, a temperature sensor, and a pressure sensor. In certain embodiments, diffraction foil 130 can be configured so that the sensor is not visible to a naked eye (e.g., to form an object, such as those discussed above). Thus, for example, a sensor can be disposed within an object present at a location as discussed above (e.g., mounted on a wall, placed on a surface, embedded within an object) so that the sensor can be used to sense changes (e.g., pressure, temperature, movement, sound, visual) in the room.

In some embodiments, object 100 can include a pattern on a surface. Exemplary patterns include a logo, a number, a letter, a word, a graph, and a design pattern. In some embodiments, diffraction foil 120 is configured so that, when light impinges on it, the diffraction foil reflects the pattern.

In some embodiments, a diffraction foil can be disposed in a photovoltaic cell. For example, the diffraction foil can be configured to direct incoming light to a photoactive layer in the photovoltaic cell.

In some embodiments, the diffraction foil can be used as an electrode in a photovoltaic cell. For example, when the diffraction foil is made of a metal, the diffraction foil itself can be used as the electrode. As another example, when the diffraction foil is made of a polymer, it can be coated with a conductive coating (e.g., a metal layer) to form the electrode. In these embodiments, the diffraction foil can be disposed in any place in the photovoltaic cell that is suitable for an electrode.

In some embodiments, the photovoltaic cell described above can be an organic photovoltaic cell. FIG. 2 shows a cross-sectional view of an organic photovoltaic cell 200 that includes a transparent substrate 210, a mesh cathode 220, a hole carrier layer 230, a photoactive layer (containing an electron acceptor material and an electron donor material) 240, a hole blocking layer 250, an anode 260, and a substrate 270.

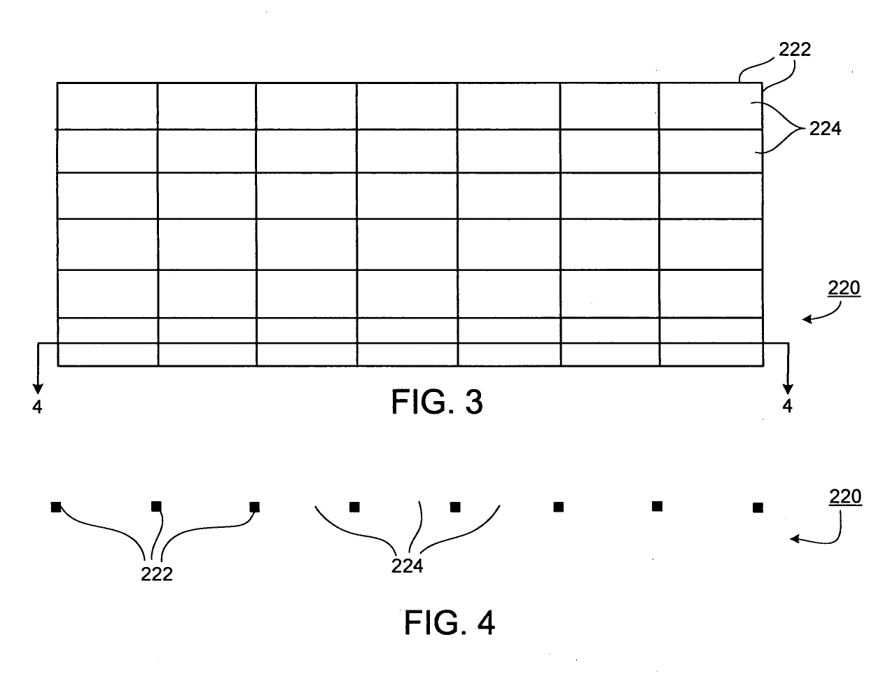

FIGS. 3 and 4 respectively show an elevational view and a cross-sectional of a mesh electrode. As shown in FIGS. 3 and 4, mesh cathode 220 includes solid regions 222 and open regions 224. In general, regions 222 are formed of electrically conducting material so that mesh cathode 220 can allow light to pass therethrough via regions 224 and conduct electrons via regions 222.

The area of mesh cathode 220 occupied by open regions 224 (the open area of mesh cathode 220) can be selected as desired. Generally, the open area of mesh cathode 220 is at least about 10% (e.g., at least about 20%, at least about 30%, at least about 40%, at least about 50%, at least about 60%, at least about 70%, at least about 80%) and/or at most about 99% (e.g., at most about 95%, at most about 90%, at most about 85%) of the total area of mesh cathode 220.

Mesh cathode 220 can be prepared in various ways. In some embodiments, mesh electrode can be stamped onto a layer (e.g., a substrate) as described above. In some embodiments, mesh cathode 220 is a woven mesh formed by weaving wires of material that form solid regions 222. The wires can be woven using, for example, a plain weave, a Dutch, weave, a twill weave, a Dutch twill weave, or combinations thereof. In certain embodiments, mesh cathode 220 is formed of a welded wire mesh. In some embodiments, mesh cathode 220 is an expanded mesh formed. An expanded metal mesh can be prepared, for example, by removing regions 224 (e.g., via laser removal, via chemical etching, via puncturing) from a sheet of material (e.g., an electrically conductive material, such as a metal), followed by stretching the sheet (e.g., stretching the sheet in two dimensions). In certain embodiments, mesh cathode 220 is a metal sheet formed by removing regions 224 (e.g., via laser removal, via chemical etching, via puncturing) without subsequently stretching the sheet.

In certain embodiments, solid regions 222 are formed entirely of an electrically conductive material (e.g., regions 222 are formed of a substantially homogeneous material that is electrically conductive). Examples of electrically conductive materials that can be used in regions 222 include electrically conductive metals, electrically conductive alloys and electrically conductive polymers. Exemplary electrically conductive metals include gold, silver, copper, aluminum, nickel, palladium, platinum and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., poly(3,4-ethelynedioxythiophene) (PEDOT)), polyanilines (e.g., doped polyanilines), polypyrroles (e.g., doped polypyrroles). In some embodiments, combinations of electrically conductive materials are used. In some embodiments, solid regions 222 can have a resistivity less than about 3 ohm per square.

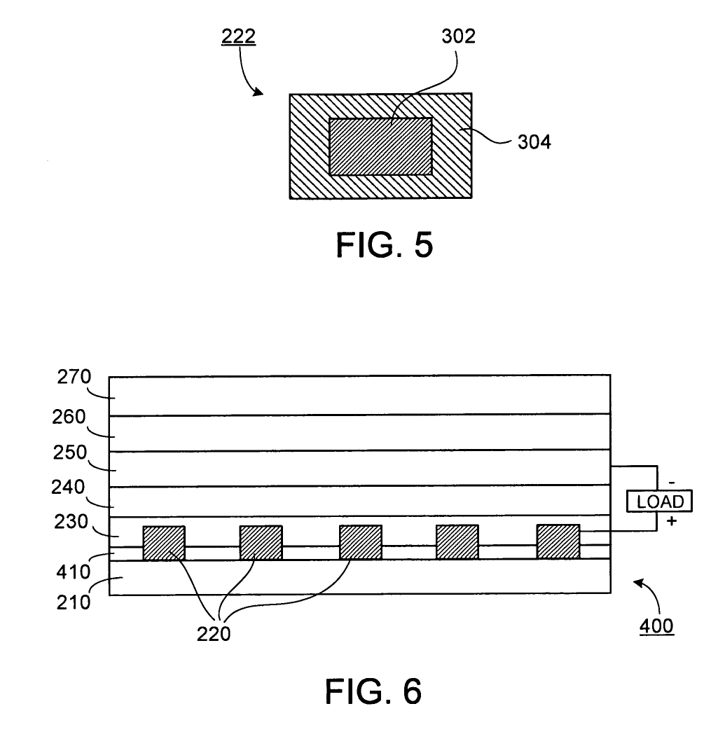

As shown in FIG. 5, in some embodiments, solid regions 222 are formed of a material 302 that is coated with a different material 304 (e.g., using metallization, using vapor deposition). In general, material 302 can be formed of any desired material (e.g., an electrically insulative material, an electrically conductive material, or a semiconductive material), and material 304 is an electrically conductive material.

Examples of electrically insulative material from which material 302 can be formed include textiles, optical fiber materials, polymeric materials (e.g., a nylon) and natural materials (e.g., flax, cotton, wool, silk). Examples of electrically conductive materials from which material 302 can be formed include the electrically conductive materials disclosed above. Examples of semiconductive materials from which material 302 can be formed include indium tin oxide, fluorinated tin oxide, tin oxide, and zinc oxide. In some embodiments, material 302 is in the form of a fiber, and material 304 is an electrically conductive material that is coated on material 302. In certain embodiments, material 302 is in the form of a mesh (see discussion above) that, after being formed into a mesh, is coated with material 304. As an example, material 302 can be an expanded metal mesh, and material 304 can be PEDOT that is coated on the expanded metal mesh.

Generally, the maximum thickness of mesh cathode 220 (i.e., the maximum thickness of mesh cathode 220 in a direction substantially perpendicular to the surface of substrate 210 in contact with mesh cathode 220) should be less than the total thickness of hole carrier layer 230. Typically, the maximum thickness of mesh cathode 220 is at least 0.1 micron (e.g., at least about 0.2 micron, at least about 0.3 micron, at least about 0.4 micron, at least about 0.5 micron, at least about 0.6 micron, at least about 0.7 micron, at least about 0.8 micron, at least about 0.9 micron, at least about one micron) and/or at most about 10 microns (e.g., at most about nine microns, at most about eight microns, at most about seven microns, at most about six microns, at most about five microns, at most about four microns, at most about three microns, at most about two microns).

While shown in FIG. 3 as having a rectangular shape, open regions 224 can generally have any desired shape (e.g., square, circle, semicircle, triangle, diamond, ellipse, trapezoid, irregular shape). In some embodiments, different open regions 224 in mesh cathode 220 can have different shapes.

Although shown in FIG. 4 as having square cross-sectional shape, solid regions 222 can generally have any desired shape (e.g., rectangle, circle, semicircle, triangle, diamond, ellipse, trapezoid, irregular shape). In some embodiments, different solid regions 222 in mesh cathode 220 can have different shapes. In embodiments where solid regions 222 have a circular cross-section, the cross-section can have a diameter in the range of about 5 microns to about 200 microns. In embodiments where solid regions 222 have a trapezoid cross-section, the cross-section can have a height in the range of about 0.1 micron to about 5 microns and a width in the range of about 5 microns to about 200 microns.

In some embodiments, mesh cathode 220 is flexible (e.g., sufficiently flexible to be incorporated in photovoltaic cell 200 using a continuous, roll-to-roll manufacturing process). In certain embodiments, mesh cathode 220 is semi-rigid or inflexible. In some embodiments, different regions of mesh cathode 220 can be flexible, semi-rigid or inflexible (e.g., one or more regions flexible and one or more different regions semi-rigid, one or more regions flexible and one or more different regions inflexible).

In general, mesh electrode 220 can be disposed on substrate 210. In some embodiments, mesh electrode 220 can be partially embedded in substrate 210.

Substrate 210 is generally formed of a transparent material. As referred to herein, a transparent material is a material which, at the thickness used in a photovoltaic cell 200, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell.

Exemplary materials from which substrate 210 can be formed include polyethylene terephthalates, polyimides, polyethylene naphthalates, polymeric hydrocarbons, cellulosic polymers, polycarbonates, polyamides, polyethers, polyether ketones, and combinations thereof. In certain embodiments, the polymer can be a fluorinated polymer. In some embodiments, combinations of polymeric materials are used. In certain embodiments, different regions of substrate 210 can be formed of different materials.

In general, substrate 210 can be flexible, semi-rigid or rigid (e.g., glass). In some embodiments, substrate 210 has a flexural modulus of less than about 5,000 megaPascals (e.g., less than about 2,500 megaPascals or less than about 1,000 megaPascals). In certain embodiments, different regions of substrate 210 can be flexible, semi-rigid or inflexible (e.g., one or more regions flexible and one or more different regions semi-rigid, one or more regions flexible and one or more different regions inflexible).

Typically, substrate 210 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 210 can be colored or non-colored. In some embodiments, one or more portions of substrate 210 is/are colored while one or more different portions of substrate 210 is/are non-colored.

Substrate 210 can have one planar surface (e.g., the surface on which light impinges), two planar surfaces (e.g., the surface on which light impinges and the opposite surface), or no planar surfaces. A non-planar surface of substrate 210 can, for example, be curved or stepped. In some embodiments, a non-planar surface of substrate 210 is patterned (e.g., having patterned steps to form a Fresnel lens, a lenticular lens or a lenticular prism).

Hole carrier layer 230 is generally formed of a material that, at the thickness used in photovoltaic cell 200, transports holes to mesh cathode 220 and substantially blocks the transport of electrons to mesh cathode 220. Examples of materials from which layer 230 can be formed include polythiophenes (e.g., PEDOT), polyanilines, polyvinylcarbazoles, polyphenylenes, polyphenylvinylenes, polysilanes, polythienylenevinylenes and/or polyisothianaphthanenes. In some embodiments, hole carrier layer 230 can include combinations of hole carrier materials.

In general, the distance between the upper surface of hole carrier layer 230 (i.e., the surface of hole carrier layer 230 in contact with active layer 240) and the upper surface of substrate 210 (i.e., the surface of substrate 210 in contact with mesh electrode 220) can be varied as desired. Typically, the distance between the upper surface of hole carrier layer 230 and the upper surface of mesh cathode 220 is at least 0.01 micron (e.g., at least about 0.05 micron, at least about 0.1 micron, at least about 0.2 micron, at least about 0.3 micron, at least about 0.5 micron) and/or at most about five microns (e.g., at most about three microns, at most about two microns, at most about one micron). In some embodiments, the distance between the upper surface of hole carrier layer 230 and the upper surface of mesh cathode 220 is from about 0.01 micron to about 0.5 micron.

Active layer 240 generally contains an electron acceptor material and an electron donor material.

Examples of electron acceptor materials include formed of fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, the electron acceptor material is a substituted fullerene (e.g., C61-phenyl-butyric acid methyl ester; PCBM). In some embodiments, active layer 240 can include a combination of electron acceptor materials.

Examples of electron donor materials include discotic liquid crystals, polythiophenes, polyphenylenes, polyphenylvinylenes, polysilanes, polythienylvinylenes, polyisothianaphthalenes, and combinations thereof. In some embodiments, the electron donor material is poly(3-hexylthiophene). In certain embodiments, active layer 240 can include a combination of electron donor materials.

Generally, active layer 240 is sufficiently thick to be relatively efficient at absorbing photons impinging thereon to form corresponding electrons and holes, and sufficiently thin to be relatively efficient at transporting the holes and electrons to layers 230 and 250, respectively. In certain embodiments, layer 240 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, layer 240 is from about 0.1 micron to about 0.2 micron thick.

Hole blocking layer 250 is generally formed of a material that, at the thickness used in photovoltaic cell 200, transports electrons to anode 260 and substantially blocks the transport of holes to anode 260. Examples of materials from which layer 250 can be formed include LiF and metal oxides (e.g., zinc oxide, titanium oxide).

Typically, hole blocking layer 250 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Anode 260 is generally formed of an electrically conductive material, such as one or more of the electrically conductive materials noted above. In some embodiments, anode 260 is formed of a combination of electrically conductive materials.

In general, substrate 270 can be identical to substrate 220. In some embodiments, substrate 270 can be different from substrate 220 (e.g., having a different shape or formed of a different material or a non-transparent material).

FIG. 6 shows a cross-sectional view of a photovoltaic cell 400 that includes an adhesive layer 410 between substrate 210 and hole carrier layer 230.

Generally, any material capable of holding mesh cathode 220 in place can be used in adhesive layer 410. In general, adhesive layer 410 is formed of a material that is transparent at the thickness used in photovoltaic cell 400. Examples of adhesives include epoxies and urethanes. Examples of commercially available materials that can be used in adhesive layer 410 include Bynel™ adhesive (DuPont) and 615 adhesive (3M). In some embodiments, layer 410 can include a fluorinated adhesive. In certain embodiments, layer 410 contains an electrically conductive adhesive. An electrically conductive adhesive can be formed of, for example, an inherently electrically conductive polymer, such as the electrically conductive polymers disclosed above (e.g., PEDOT). An electrically conductive adhesive can be also formed of a polymer (e.g., a polymer that is not inherently electrically conductive) that contains one or more electrically conductive materials (e.g., electrically conductive particles). In some embodiments, layer 410 contains an inherently electrically conductive polymer that contains one or more electrically conductive materials.

In some embodiments, the thickness of layer 410 (i.e., the thickness of layer 410 in a direction substantially perpendicular to the surface of substrate 210 in contact with layer 410) is less thick than the maximum thickness of mesh cathode 220. In some embodiments, the thickness of layer 410 is at most about 90% (e.g., at most about 80%, at most about 70%, at most about 60%, at most about 50%, at most about 40%, at most about 30%, at most about 20%) of the maximum thickness of mesh cathode 220. In certain embodiments, however, the thickness of layer 410 is about the same as, or greater than, the maximum thickness of mesh cathode 220.

In general, a photovoltaic cell having a mesh cathode can be manufactured as desired.

In some embodiments, a photovoltaic cell can be prepared as follows. Electrode 260 is formed on substrate 270 using conventional techniques, and hole-blocking layer 250 is formed on electrode 260 (e.g., using a vacuum deposition process or a solution coating process). Active layer 240 is formed on hole-blocking layer 250 (e.g., using a solution coating process, such as slot coating, spin coating or gravure coating). Hole carrier layer 230 is formed on active layer 240 (e.g., using a solution coating process, such as slot coating, spin coating or gravure coating). Mesh cathode 220 is partially disposed in hole carrier layer 230 (e.g., by a stamping method described above).

Substrate 210 is then formed on mesh cathode 220 and hole carrier layer 230 using conventional methods.

In certain embodiments, a photovoltaic cell can be prepared as follows. Electrode 260 is formed on substrate 270 using conventional techniques, and hole-blocking layer 250 is formed on electrode 260 (e.g., using a vacuum deposition or a solution coating process). Active layer 240 is formed on hole-blocking layer 250 (e.g., using a solution coating process, such as slot coating, spin coating or gravure coating). Hole carrier layer 230 is formed on active layer 240 (e.g., using a solution coating process, such as slot coating, spin coating or gravure coating). Adhesive layer 410 is disposed on hole carrier layer 230 using conventional methods. Mesh cathode 220 is partially disposed in adhesive layer 410 and hole carrier layer 230 (e.g., by disposing mesh cathode 220 on the surface of adhesive layer 410, and pressing mesh cathode 220). Substrate 210 is then formed on mesh cathode 220 and adhesive layer 410 using conventional methods.

While the foregoing processes involve partially disposing mesh cathode 220 in hole carrier layer 230, in some embodiments, mesh cathode 220 is formed by printing the cathode material on the surface of hole carrier layer 230 or adhesive layer 410 to provide an electrode having the open structure shown in the figures. For example, mesh cathode 220 can be printed using stamping, dip coating, extrusion coating, spray coating, inkjet printing, screen printing, and gravure printing. The cathode material can be disposed in a paste which solidifies upon heating or radiation (e.g., UV radiation, visible radiation, IR radiation, electron beam radiation). The cathode material can be, for example, vacuum deposited in a mesh pattern through a screen or after deposition it may be patterned by photolithography.

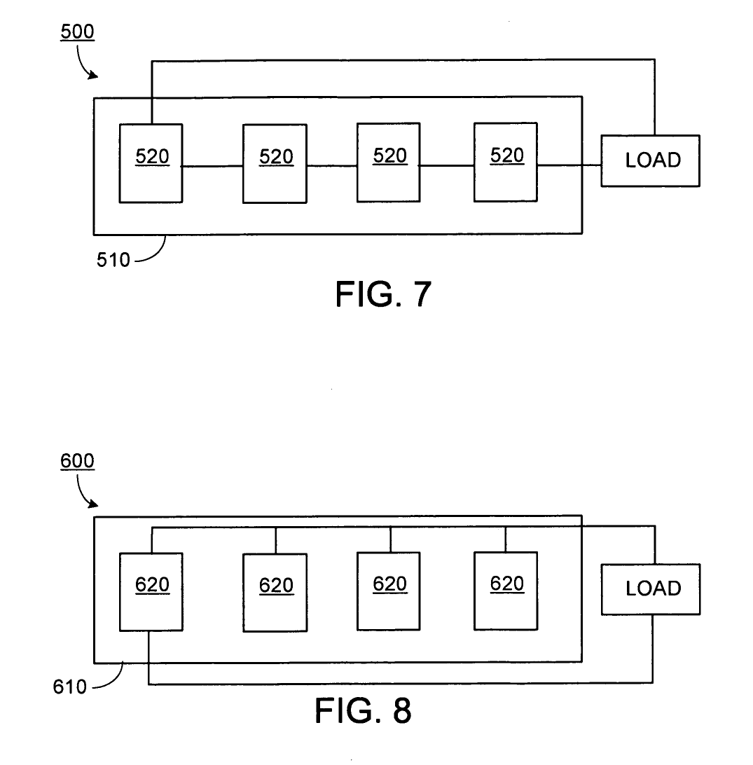

Multiple photovoltaic cells can be electrically connected to form a photovoltaic system. As an example, FIG. 7 is a schematic of a photovoltaic system 500 having a module 510 containing photovoltaic cells 520. Cells 520 are electrically connected in series, and system 500 is electrically connected to a load. As another example, FIG. 8 is a schematic of a photovoltaic system 600 having a module 610 that contains photovoltaic cells 620. Cells 620 are electrically connected in parallel, and system 600 is electrically connected to a load. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

In some embodiments, photovoltaic systems containing a plurality of photovoltaic cells can be fabricated using continuous manufacturing processes, such as roll-to-roll or web processes. In some embodiments, a continuous manufacturing process includes: forming a group of photovoltaic cell portions on a first advancing substrate; disposing an electrically insulative material between at least two of the cell portions on the first substrate; embedding a wire in the electrically insulative material between at least two photovoltaic cell portions on the first substrate; forming a group of photovoltaic cell portion on a second advancing substrate; combining the first and second substrates and photovoltaic cell portions to form a plurality of photovoltaic cells, in which at least two photovoltaic cells are electrically connected in series by the wire. In some embodiments, the first and second substrates can be continuously advanced, periodically advanced, or irregularly advanced.

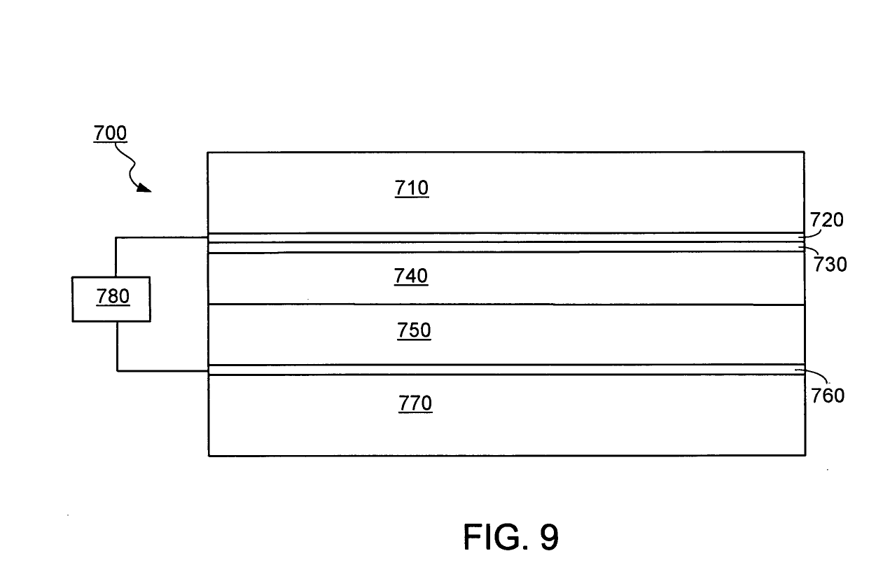

In some embodiments, the stamping methods described above can be used to print an electrode on a substrate for use in a DSSC. FIG. 9 is a cross-sectional view of DSSC 700 that includes a substrate 710, an electrode 720, a catalyst layer 730, a charge carrier layer 740, a photoactive layer 750, an electrode 760, a substrate 770, and an external load 780. Examples of DSSCs are discussed in U.S. patent application Ser. No. 11/311,805 filed Dec. 19, 2005 and Ser. No. 11/269,956 filed on Nov. 9, 2005, the contents of which are hereby incorporated by reference.

In some embodiments, the stamping methods described above can be used to print an electrode on a substrate for use in a tandem cell. Examples of tandem photovoltaic cells are discussed in U.S. patent application Ser. No. 10/558,878 and U.S. Provisional Application Ser. Nos. 60/790,606, 60/792,635, 60/792,485, 60/793,442, 60/795,103, 60/797,881, and 60/798,258, the contents of which are hereby incorporated by reference.

While certain embodiments have been disclosed, other embodiments are also possible.

As one example, while cathodes formed of mesh have been described, in some embodiments a mesh anode can be used. This can be desirable, for example, when light transmitted by the anode is used. In certain embodiments, both a mesh cathode and a mesh anode are used. This can be desirable, for example, when light transmitted by both the cathode and the anode is used.

As another example, while embodiments have generally been described in which light that is transmitted via the cathode side of the cell is used, in certain embodiments light transmitted by the anode side of the cell is used (e.g., when a mesh anode is used). In some embodiments, light transmitted by both the cathode and anode sides of the cell is used (when a mesh cathode and a mesh anode are used).

As another example, while cathodes formed of mesh have been described, in some embodiments a non-mesh cathode can be used. In certain embodiments, both a non-mesh cathode and a non-mesh anode are used.

As a further example, while electrodes (e.g., mesh electrodes, non-mesh electrodes) have been described as being formed of electrically conductive materials, in some embodiments a photovoltaic cell may include one or more electrodes (e.g., one or more mesh electrodes, one or more non-mesh electrodes) formed of a semiconductive material. Examples of semiconductive materials include indium tin oxide, fluorinated tin oxide, tin oxide, and zinc oxide.

As an additional example, in some embodiments, one or more semiconductive materials can be disposed in the open regions of a mesh electrode (e.g., in the open regions of a mesh cathode, in the open regions of a mesh anode, in the open regions of a mesh cathode and the open regions of a mesh anode). Examples of semiconductive materials include tin oxide, fluorinated tin oxide, tin oxide and zinc oxide. Other semiconductive materials, such as partially transparent semiconductive polymers, can also be disposed in the open regions of a mesh electrode. For example, a partially transparent polymer can be a polymer which, at the thickness used in a photovoltaic cell, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell.

Typically, the semiconductive material disposed in an open region of a mesh electrode is transparent at the thickness used in the photovoltaic cell.

As another example, in certain embodiments, a protective layer can be applied to one or both of the substrates. A protective layer can be used to, for example, keep contaminants (e.g., dirt, water, oxygen, chemicals) out of a photovoltaic cell and/or to ruggedize the cell. In certain embodiments, a protective layer can be formed of a polymer (e.g., a fluorinated polymer).

As a further example, while certain types of photovoltaic cells have been described that have one or more mesh electrodes, one or more mesh electrodes (mesh cathode, mesh anode, mesh cathode and mesh anode) can be used in other types of photovoltaic cells as well. Examples of such photovoltaic cells include photoactive cells with an active material formed of amorphous silicon, cadmium selenide, cadmium telluride, copper indium sulfide, and copper indium gallium selenide.

As an additional example, while described as being formed of different materials, in some embodiments materials 302 and 304 are formed of the same material.

As another example, although shown in FIG. 5 as being formed of one material coated on a different material, in some embodiments solid regions 222 can be formed of more than two coated materials (e.g., three coated materials, four coated materials, five coated materials, six coated materials).

Other embodiments are in the claims.

What is claimed is:

1. A photovoltaic cell comprising a diffraction foil.

2. The photovoltaic cell of claim 1, wherein the diffraction foil comprises a metal.

3. The photovoltaic cell of claim 2, wherein the metal comprises aluminum, chromium, copper, silver, gold, or an alloy thereof.

4. The photovoltaic cell of claim 1, wherein the diffraction foil comprises a polymer.

5. The photovoltaic cell of claim 1, wherein the article comprises an electrically conductive layer coated on the diffraction foil.

6. The photovoltaic cell of claim 1, wherein the diffraction foil is configured as at least a portion of an electrode.

7. The photovoltaic cell of claim 1, wherein the photovoltaic cell further comprises a photoactive material.

8. The photovoltaic cell of claim 7, wherein the photoactive material comprises an electron donor material and an electron acceptor material.

9. The photovoltaic cell of claim 8, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

10. The photovoltaic cell of claim 8, wherein the electron donor material comprises a material selected from the group consisting of discotic liquid crystals, polythiophenes, polyphenylenes, polyphenylvinylenes, polysilanes, polythienylvinylenes, and polyisothianaphthalenes.

11. The photovoltaic cell of claim 7, wherein the photoactive material comprises a photosensitized interconnected nanoparticle material.

12. The photovoltaic cell of claim 11, wherein the photosensitized interconnected nanoparticle material comprises a material selected from the group consisting of selenides, sulfides, tellurides, titanium oxides, tungsten oxides, zinc oxides, zirconium oxides, and combinations thereof.

13. The photovoltaic cell of claim 7, wherein the photoactive material comprises amorphous silicon or CIGS.

14. The photovoltaic cell of claim 1, wherein the diffraction foil is configured to direct incoming light to the photoactive layer.

15. The photovoltaic cell of claim 1, further comprising two substrates, the diffraction foil being disposed between first and second substrates.

16. An article, comprising:
a substrate;
an photovoltaic cell disposed on the substrate; and
a diffraction foil disposed on the photovoltaic cell.

17. The article of claim 16, wherein the article includes a pattern on a surface.

18. The article of claim 17, wherein the pattern comprises a logo, a number, a letter, a word, a graph, or a design pattern.

19. The article of claim 17, wherein the diffraction foil is configured so that, when light impinges on the diffraction foil, the diffraction foil reflects the pattern.

20. The article of claim 16, wherein the article comprises a security card, an identification card, a greeting card, a business card, an advertising board, a poster, or a sign.

21. A system, comprising:
a photovoltaic cell;
a sensor electrically connected with the photovoltaic cell; and
a diffraction foil at least partially covering the photovoltaic cell.

22. The system of claim 21, wherein the sensor is a video sensor, an audio sensor, a movement detecting sensor, a temperature sensor, or a pressure sensor.

23. The system of claim 21, wherein the system is configured to be mounted on a wall.

24. The system of claim 21, wherein the system is configured so that the photovoltaic cell is not visible to a naked eye.

25. The system of claim 21, wherein the system is configured so that the sensor is not visible to a naked eye.

26. The system of claim 21, wherein, during use, the sensor is at least partially powered by the photovoltaic cell.
